(19) United States
(12) Patent Application Publication
(10) Pub. No.: US 2017/0287428 A1
(43) Pub. Date: Oct. 5, 2017

(54) GATE DRIVING CIRCUIT AND METHOD OF DRIVING THE SAME, DISPLAY PANEL

(71) Applicants: Boe Technology Group Co., Ltd., Beijing (CN); Hefei Boe Optoelectronics Technology Co., Ltd., Anhui (CN)

(72) Inventors: Wei Xue, Beijing (CN); Bo Liu, Beijing (CN); Hongmin Li, Beijing (CN); Ping Song, Beijing (CN)

(21) Appl. No.: 15/509,589

(22) PCT Filed: Aug. 12, 2016
(86) PCT No.: PCT/CN2016/094854

§ 371 Date: Mar. 8, 2017

(30) Foreign Application Priority Data
Oct. 23, 2015 (CN) 201510692249

(51) Int. Cl. G09G 3/36; H01L 27/12; G11C 19/28

(52) U.S. Cl. CPC G09G 3/3677; G11C 19/287; H01L 27/1214; G09G 2310/08; G09G 2310/0286; G09G 2310/0283

(57) ABSTRACT

The present disclosure provides a gate driving circuit comprising multiple stages of cascaded shift registers, each stage of shift register comprising an input subcircuit, a first reset subcircuit, a second reset subcircuit, an energy storage subcircuit, an output subcircuit and a pull-down node potential generation subcircuit, wherein at least two stages of shift registers share a pull-down node potential generation subcircuit. The present disclosure further provides a display panel comprising the gate driving circuit, and a method for driving the gate driving circuit.

### RELATED APPLICATIONS

The present application is the U.S. national phase entry of PCT/CN2016/094854, with an international filing date of Aug. 12, 2016, which claims the benefit of Chinese Patent Applications No. 201510692249.8, filed on Oct. 23, 2015, the entire disclosures of which are incorporated herein by reference.

### FIELD

The present disclosure generally relates to the field of display technologies, and more particularly to a gate driving circuit, a method of driving the gate driving circuit and a display panel comprising the gate driving circuit.

### BACKGROUND

With the development of display technologies, liquid crystal display devices are more and more widely used. The liquid crystal display device generally comprises a color film substrate and an array substrate arranged opposite to each other, between which a liquid crystal is provided. The array substrate is provided with a source driving circuit and a gate driving circuit (GOA), which are both located at edge positions of the array substrate. Since the gate driving circuit is usually disposed at an edge position of the array substrate, one of the problems to be solved in the art is how to reduce the space occupied by the gate driving circuit to thereby realize a narrow frame design of the display device.

In the existing design of a gate driving circuit, each gate line controls turn-on and turn-off by means of its respective shift register. In the shift register, the most important electric potential points include a pull-up node and a pull-down node. When the shift register is operating, the pull-up node bootstrap control produces a shift register output, while pulling down the potential of the pull-down node. When the shift register is turned off, the pull-down node is at a high level potential, thereby pulling down the potential of the pull-up node. In the prior art design, each stage of shift register comprises a pull-down node potential generation unit. Such a design would increase the size of the display device frame and make it difficult to realize a narrow frame design.

### SUMMARY

It is an objective of the present disclosure to provide a gate driving circuit, a method of driving the same, and a display panel, which can at least partially alleviate or eliminate one or more of the above-mentioned problems in the prior art.

According to a first aspect of the present disclosure, there is provided a gate driving circuit, comprising multiple stages of cascaded shift registers, wherein at least two stages of shift registers share a pull-down node potential generation subcircuit.

In the gate driving circuit proposed by the present disclosure, the number of pull-down node potential generation subcircuits required in the gate driving circuit can be reduced by sharing a pull-down node potential generation subcircuit between at least two stages of shift registers, thereby reducing the space occupied by the gate driving circuit. Accordingly, as compared to the prior art design where each stage of shift register comprises a pull-down node potential generation subcircuit, the proposed design of the gate driving circuit can realize a display panel with a narrower frame.

According to embodiments of the present disclosure, a shift signal input terminal of a first stage of shift register and a reset signal input terminal of a last stage of shift register are connected to a start signal line, and a shift signal output terminal of each stage of shift register is connected to a reset signal input terminal of a previous stage of shift register and a shift signal input terminal of a next stage of shift register. Further, for each stage of shift register, a first signal input terminal is connected to a first signal line, a second signal input terminal is connected to a second signal line, a first level signal input terminal is connected to a first level signal line, and a second level signal input terminal is connected to a second level signal line. A clock signal input terminal of an odd-numbered stage of shift register is connected to a first clock signal line, and a clock signal input terminal of an even-numbered stage of shift register is connected to a second clock signal line. Each stage of shift register may comprise an input subcircuit, a first reset subcircuit, a second reset subcircuit, an energy storage subcircuit, an output subcircuit and the pull-down node potential generation subcircuit. The input subcircuit is connected to the first signal input terminal, the shift signal input terminal and the first reset subcircuit, the first reset subcircuit is connected to the reset signal input terminal and the second signal input terminal, the second reset subcircuit is connected to a pull-down node, a transition node, a pull-up node, the shift signal output terminal and the second level signal input terminal, the energy storage subcircuit is connected to the pull-up node, the output subcircuit is connected to the clock signal input terminal, the shift signal output terminal and the pull-up node, and the pull-down node potential generation subcircuit is connected to the first level signal input terminal, the transition node and the pull-down node.

According to an embodiment of the present disclosure, the pull-down node potential generation subcircuit may comprises a first transistor and a second transistor, wherein a gate and a first terminal of the first transistor are connected to the first level signal input terminal, a second terminal of the first transistor and a gate of the second transistor are connected to the transition node, a first terminal of the second transistor is connected to the first level signal input terminal, and a second terminal of the second transistor is connected to the pull-down node.

According to another embodiment of the present disclosure, the input subcircuit may comprise a third transistor, wherein a gate of the third transistor is connected to the shift signal input terminal, a first terminal of the third transistor is connected to the first signal input terminal, and a second terminal of the third transistor is connected to the first reset subcircuit.

According to a further embodiment of the present disclosure, the first reset subcircuit may comprise a fourth transistor, wherein a gate of the fourth transistor is connected to the reset signal input terminal, a first terminal of the fourth transistor is connected to the input subcircuit, and a second terminal of the fourth transistor is connected to the second signal input terminal.

According to yet another embodiment of the present disclosure, the second reset subcircuit may comprise a fifth transistor, a sixth transistor, a seventh transistor, an eighth transistor and a ninth transistor, wherein second terminals of the fifth transistor, the sixth transistor, the seventh transistor, the eighth transistor and the ninth transistor are connected to the second level signal input terminal, a gate of the fifth transistor, a first terminal of the seventh transistor and a gate of the eighth transistor are connected to the pull-down node, a first terminal of the fifth transistor, a gate of the sixth transistor and a gate of the seventh transistor are connected to the pull-up node, a first terminal of the sixth transistor is connected to the transition node, a first terminal of the seventh transistor is connected to the pull-down node, a first terminal of the eighth transistor and a first terminal of the ninth transistor are connected to the shift signal output terminal, and a gate of the ninth transistor is connected to the second level signal input terminal.

According to an embodiment of the present disclosure, the output subcircuit may comprise a tenth transistor, wherein a gate of the tenth transistor is connected to the pull-up node, a first terminal of the tenth transistor is connected to the clock signal input terminal, and a second terminal of the tenth transistor is connected to the shift signal output terminal.

According to another embodiment of the present disclosure, the energy storage subcircuit may comprise a capacitor, wherein a first terminal of the capacitor is connected to the pull-up node, and a second terminal of the capacitor is connected to the output subcircuit.

In the above embodiments, the respective transistors may all be N-type transistors. At that time, the first level signal line inputs a high level, and the second level signal line inputs a low level. Alternatively, the respective transistors may all be P-type transistors. At that time, the first level signal line inputs a low level, and the second level signal line inputs a high level.

It is to be noted that the first terminal of the respective transistors may be a source and the second terminal thereof may be a drain. Alternatively, the first terminal of the respective transistors may be a drain, and the second terminal thereof may be a source, which are not particularly limited here.

According to a second aspect of the present disclosure, there is provided a display panel, comprising the gate driving circuit as described in any of the foregoing embodiments. In this display panel, the number of pull-down node potential generation subcircuits required in the gate driving circuit can be reduced by sharing a pull-down node potential generation subcircuit between at least two stages of shift registers in the gate driving circuit, thereby reducing the space occupied by the gate driving circuit. As compared to the prior art design where each stage of shift register comprises a pull-down node potential generation subcircuit, the display panel may have a narrower frame.

According to a third aspect of the present disclosure, there is provided a driving method for driving the gate driving circuit as described in any one of the foregoing embodiments. The driving method may comprise: upon forward scanning, applying a start pulse having a first level on the start signal line, applying a signal having a first level on the first signal line, and applying a signal having a second level on the second signal line; upon reverse scanning, applying a start pulse having a first level on the start signal line, applying a signal having a second level on the first signal line, and applying a signal having a first level on the second signal line, wherein at least two stages of shift registers in the gate driving circuit may share a pull-down node potential generation subcircuit.

The above driving method of the gate driving circuit has embodiments and advantages corresponding to or similar to those of the gate driving circuit as described in the first aspect of the present disclosure, which will not be described here for simplicity.

In the present disclosure, the number of pull-down node potential generation subcircuits required in the gate driving circuit can be reduced by sharing a pull-down node potential generation subcircuit between at least two stages of shift registers, thereby reducing the space occupied by the gate driving circuit. Accordingly, as compared to the prior art design where each stage of shift register comprises a pull-down node potential generation subcircuit, the proposed design of the gate driving circuit can realize a display panel having a narrower frame.

### BRIEF DESCRIPTION OF DRAWINGS

These and other aspects of the present disclosure will now be described in more detail with reference to the drawings that illustrate embodiments of the present disclosure, wherein the drawings are not drawn to scale and are intended to illustrate the principles of the present disclosure. In the drawings:

FIG. 1 is a schematic diagram showing the structure of a portion of a gate driving circuit according to an embodiment of the present disclosure;

FIG. 2 is a schematic diagram showing the structure of a shift register according to an embodiment of the present disclosure;

FIG. 3 is a schematic diagram showing the circuit configuration of a shift register according to an embodiment of the present disclosure; and

FIG. 4 is a timing diagram of key signals when the shift register in FIG. 3 operates during forward scanning.

### DETAILED DESCRIPTION

The present disclosure will now be described more comprehensively below with reference to the accompanying drawings, in which the currently preferred embodiments of the present disclosure are shown. However, the present disclosure may be embodied in many different forms and should not be construed as being limited to the embodiments set forth herein; instead, these embodiments are provided for completeness and thoroughness and to provide those skilled in the art with a thorough understanding of the scope of the present disclosure.

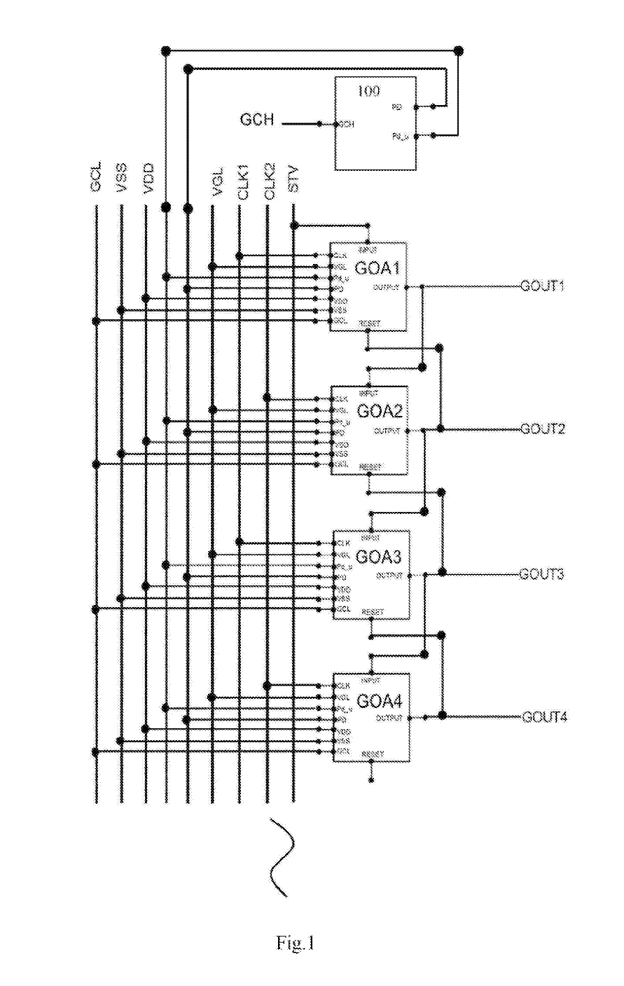

FIG. 1 illustrates a schematic diagram of the structure of a portion of a gate driving circuit according to an embodiment of the present disclosure. As shown in FIG. 1, the gate driving circuit comprises multiple stages of cascaded shift registers GOA1, GOA2, GOA3, GOA4, wherein a shift signal input terminal INPUT of a first stage of shift register GOA1 and a reset signal input terminal (not shown) of a last stage of shift register are connected to a start signal line STV, a shift signal output terminal OUTPUT of each stage of shift register is connected to a reset signal input terminal RESET of the previous stage of shift register and the shift signal input terminal INPUT of the next stage of shift register, and the shift signal output terminal OUTPUT of each stage of shift register outputs a shift signal GOUT to a respective gate line. For each stage of shift register, a first signal input terminal VDD is connected to a first signal line, a second signal input terminal VSS is connected to a second signal line, and a second level signal input terminal GCL/VGL is connected to a second level signal line. A clock signal input terminal CLK of an odd-numbered stage of shift register is connected to a first clock signal line CLK1, and a clock signal input terminal CLK of an even-numbered stage of shift register is connected to a second clock signal line CLK2. The gate driving circuit further comprises a pull-down node potential generation subcircuit 100 shared among the multiple stages of shift registers GOA1, GOA2, GOA3, GOA4, wherein a first level signal input terminal GCH of the pull-down node potential generation subcircuit 100 is connected to a first level signal line, and the pull-down node potential generation subcircuit 100 is connected to a respective shift register via a transition node Pd_u and a pull-down node PD.

It is to be noted that, although four stages of shift registers GOA1, GOA2, GOA3, GOA4 are shown in FIG. 1, this is merely an example and the gate driving circuit may comprise more or fewer shift registers as required.

It is to be further noted that, although the pull-down node potential generation subcircuit 100 shown in FIG. 1 is shared among successive four stages of shift registers GOA1, GOA2, GOA3, GOA4, the pull-down node potential generation subcircuit 100 may be shared among any number of shift registers, in particular at least two, and the pull-down node potential generation subcircuit 100 may be shared among dis-successive shift registers, for example, among odd-numbered stages of shift registers or even-numbered stages of shift registers.

In this embodiment, the number of pull-down node potential generation subcircuits required in the gate driving circuit can be reduced by sharing the pull-down node potential generation subcircuit between at least two stages of shift registers, thereby reducing the space occupied by the gate driving circuit. Accordingly, as compared to the prior art design where each stage of shift register comprises a pull-down node potential generation subcircuit, the proposed design of the gate driving circuit can realize a display panel having a narrower frame.

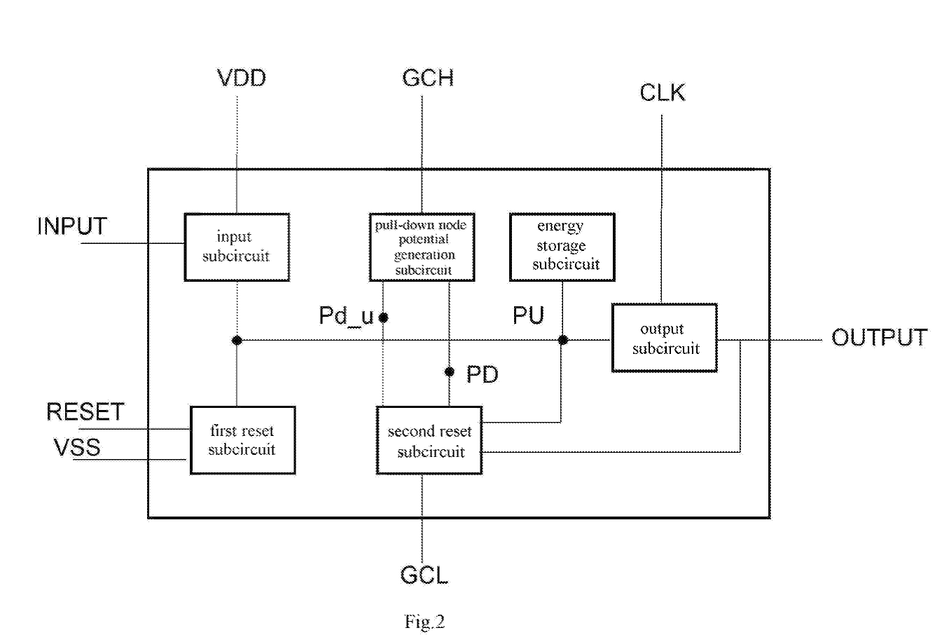

FIG. 2 illustrates a schematic diagram of the structure of a shift register according to an embodiment of the present disclosure. As shown in FIG. 2, each stage of shift register comprises an input subcircuit, a first reset subcircuit, a second reset subcircuit, an energy storage subcircuit, an output subcircuit and the pull-down node potential generation subcircuit. The input subcircuit is connected to the first signal input terminal VDD, the shift signal input terminal INPUT and the first reset subcircuit. The first reset subcircuit is connected to the reset signal input terminal RESET and the second signal input terminal VSS. The second reset subcircuit is connected to the pull-down node PD, the transition node Pd_u, and the pull-up node PU. The shift signal output terminal OUTPUT is connected to the second level signal input terminal GCL. The energy storage subcircuit is connected to the pull-up node PU. The output subcircuit is connected to the clock signal input terminal CLK, the shift signal output terminal OUTPUT and the pull-up node PU. The pull-down node potential generation subcircuit is connected to the first level signal input terminal GCH, the transition node Pd_u and the pull-down node PD. When a plurality of such shift registers are used in the gate driving circuit, at least two stages of shift registers share a pull-down node potential generation subcircuit.

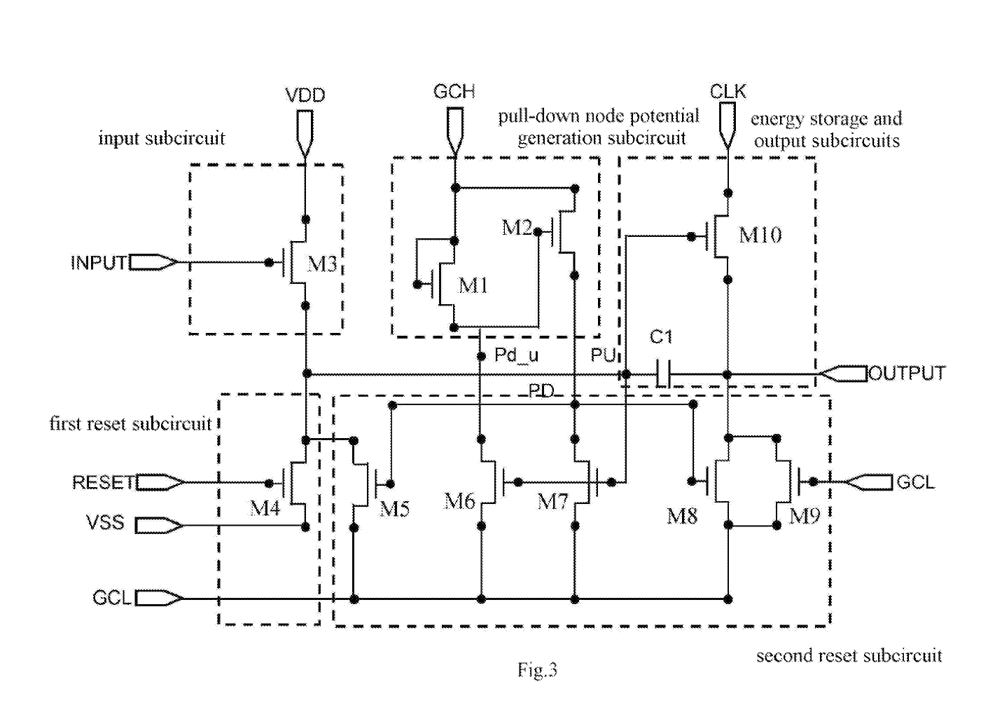

FIG. 3 illustrates a schematic diagram of the circuit configuration of a shift register according to an embodiment of the present disclosure.

As shown in FIG. 3, the pull-down node potential generation subcircuit comprises a first transistor M1 and a second transistor M2. The gate and the first terminal of the first transistor M1 are connected to the first level signal input terminal GCH, the second terminal of the first transistor M1 and the gate of the second transistor M2 are connected to the transition node Pd_u, the first terminal of the second transistor M2 is connected to the first level signal input terminal GCH, and the second terminal of the second transistor M2 is connected to the pull-down node PD.

The input subcircuit comprises a third transistor M3. The gate of the third transistor M3 is connected to the shift signal input terminal INPUT, the first terminal of the third transistor M3 is connected to the first signal input terminal VDD, and the second terminal of the third transistor M3 is connected to the first reset subcircuit.

The first reset subcircuit comprises a fourth transistor M4. The gate of the fourth transistor M4 is connected to the reset signal input terminal RESET, the first terminal of the fourth transistor M4 is connected to the input subcircuit, and the second terminal of the fourth transistor M4 is connected to the second signal input terminal VSS.

The second reset subcircuit comprises a fifth transistor M5, a sixth transistor M6, a seventh transistor M7, an eighth transistor M8, and a ninth transistor M9, wherein the second terminals of the fifth transistor M5, the sixth transistor M6, the seventh transistor M7, the eighth transistor M8 and the ninth transistor M9 are connected to the second level signal input terminal GCL. The gate of the fifth transistor M5, the first terminal of the seventh transistor M7, and the gate of the eighth transistor M8 are connected to the pull-down node PD. The first terminal of the fifth transistor M5, the gate of the sixth transistor M6 and the gate of the seventh transistor M7 are connected to the pull-up node PU. The first terminal of the sixth transistor M6 is connected to the transition node Pd_u. The first terminal of the seventh transistor M7 is connected to the pull-down node PD. The first terminal of the eighth transistor M8 is connected to the first terminal of the ninth transistor M9 and the shift signal output terminal OUTPUT. The gate of the ninth transistor M9 is connected to the second level signal input terminal GCL.

The output subcircuit comprises a tenth transistor M10. The gate of the tenth transistor M10 is connected to the pull-up node PU, the first terminal of the tenth transistor M10 is connected to the clock signal input terminal CLK, and the second terminal of the tenth transistor M10 is connected to the shift signal output terminal OUTPUT.

The energy storage subcircuit comprises a capacitor C1. The first terminal of the capacitor C1 is connected to the pull-up node PU, and the second terminal of the capacitor C1 is connected to the output subcircuit.

It is to be noted that, in an exemplary implementation, the above transistors may all be N-type transistors. At that time, the first level signal line of a respective gate driving circuit inputs a high level and the second level signal line inputs a low level. In another exemplary implementation, the respective transistors may all be P-type transistors. At that time, the first level signal line of a respective gate driving circuit inputs a low level and the second level signal line inputs a high level.

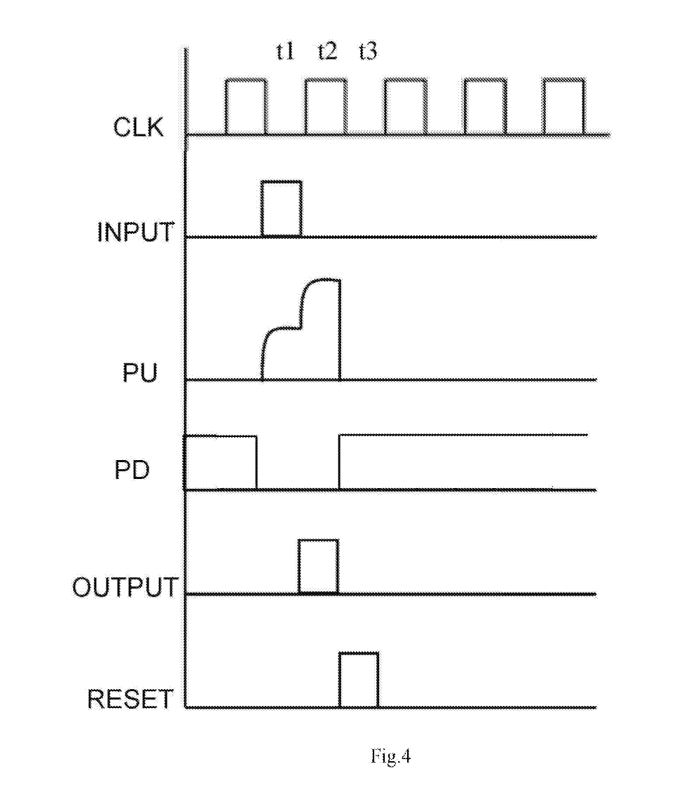

FIG. 4 illustrates a timing diagram of key signals when the shift register shown in FIG. 3 operates during forward scanning based on the example that the transistors in FIG. 3 are all N-type transistors. In the example of FIG. 4, it is assumed that a high level signal is always input to the first signal input terminal VDD, a low level signal is always input to the second signal input terminal VSS, a high level signal is always input to the first level signal input terminal GCH, and a low level signal is always input to the second level signal input terminal GCL.

As shown in FIG. 4, in the phase t1, a high level signal is input to the shift signal input terminal INPUT of the shift register, causing the first transistor M1 of the input subcircuit to be turned on, thereby pulling up the potential of the pull-up node PU. As a result, the first capacitor C1 of the energy storage subcircuit is charged and the sixth transistor M6 and the eighth transistor M8 of the second reset subcircuit are turned on, thereby pulling down the potential of the pull-down node PD.

In the phase t2, since the pull-up node PU is at a high potential, the third transistor M3 of the output subcircuit is turned on, so that the shift signal output terminal OUTPUT of the shift register outputs a high level. Since the voltage difference between the two terminals of the capacitor C1 is kept constant, the potential of the pull-up node PU is further pulled up.

In the phase t3, a high level signal is input to the reset signal input terminal RESET of the shift register, causing the second transistor M2 of the first reset subcircuit to be turned on. Since a low level signal is input to the second signal input terminal VSS during the period of the phase t3, the potential of the pull-up node PU is pulled down. As a result, the sixth transistor M6 and the eighth transistor M8 of the second reset subcircuit are turned off, and the second transistor M2 of the pull-down node potential generation subcircuit is turned on, thereby pulling up the potential of the pull-down node PD.

As will be easily appreciated by those skilled in the art, when the shift register operates during reverse scanning, a low level signal is input to the first signal input terminal VDD and a high level signal is input to the second signal input terminal VSS.

In an exemplary embodiment, the present disclosure further provides a display panel comprising the gate driving circuit described in any of the foregoing embodiments.

In addition, there is further provided a method of driving a gate driving circuit, comprising: upon forward scanning, applying a start pulse having a first level on the start signal line, applying a signal having a first level on the first signal line, and applying a signal having a second level on the second signal line; upon reverse scanning, applying a start pulse having a first level on the start signal line, applying a signal having a second level on the first signal line, and applying a signal having a first level on the second signal line, wherein at least two stages of shift registers of the gate driving circuit share a pull-down node potential generation subcircuit.

The present disclosure can be widely applied to various display devices and apparatuses having display device, such as a mobile phone, a notebook computer, a liquid crystal television, and the like.

Those skilled in the art will recognize that the present disclosure is in no way limited to the exemplary embodiments described above. On the contrary, many modifications and variations are possible within the scope of the appended claims. In the claims, the word “comprising” does not exclude other elements or steps. The mere fact that certain measures are recited in mutually different dependent claims does not indicate that a combination of these measures cannot be used to advantage.

1. A gate driving circuit, comprising multiple stages of cascaded shift registers, wherein at least two stages of shift registers share a pull-down node potential generation subcircuit.

2. The gate driving circuit according to claim 1, wherein a shift signal input terminal of a first stage of shift register and a reset signal input terminal of a last stage of shift register are connected to a start signal line, a shift signal output terminal of each stage of shift register is connected to a reset signal input terminal of a previous stage of shift register and a shift signal input terminal of a next stage of shift register, and
for each stage of shift register,
a first signal input terminal is connected to a first signal line, a second signal input terminal is connected to a second signal line, a first level signal input terminal is connected to a first level signal line, and a second level signal input terminal is connected to a second level signal line, and
a clock signal input terminal of an odd-numbered stage of shift register is connected to a first clock signal line, and a clock signal input terminal of an even-numbered stage of shift register is connected to a second clock signal line,
each stage of shift register comprises an input subcircuit, a first reset subcircuit, a second reset subcircuit, an energy storage subcircuit, an output subcircuit and the pull-down node potential generation subcircuit,
the input subcircuit is connected to the first signal input terminal, the shift signal input terminal and the first reset subcircuit,
the first reset subcircuit is connected to the reset signal input terminal and the second signal input terminal,
the second reset subcircuit is connected to a pull-down node, a transition node, a pull-up node, the shift signal output terminal and the second level signal input terminal,
the energy storage subcircuit is connected to the pull-up node,
the output subcircuit is connected to the clock signal input terminal, the shift signal output terminal and the pull-up node, and
the pull-down node potential generation subcircuit is connected to the first level signal input terminal, the transition node and the pull-down node.

3. The gate driving circuit according to claim 2, wherein the pull-down node potential generation subcircuit comprises a first transistor and a second transistor, a gate and a first terminal of the first transistor are connected to the first level signal input terminal, a second terminal of the first transistor and a gate of the second transistor are connected to the transition node, a first terminal of the second transistor is connected to the first level signal input terminal, and a second terminal of the second transistor is connected to the pull-down node.

4. The gate driving circuit according to claim 2, wherein the input subcircuit comprises a third transistor, a gate of the third transistor is connected to the shift signal input terminal, a first terminal of the third transistor is connected to the first signal input terminal, and a second terminal of the third transistor is connected to the first reset subcircuit.

5. The gate driving circuit according to claim 2, wherein the first reset subcircuit comprises a fourth transistor, a gate of the fourth transistor is connected to the reset signal input terminal, a first terminal of the fourth transistor is connected to the input subcircuit, and a second terminal of the fourth transistor is connected to the second signal input terminal.

6. The gate driving circuit according to claim 2, wherein the second reset subcircuit comprises a fifth transistor, a sixth transistor, a seventh transistor, an eighth transistor and a ninth transistor, second terminals of the fifth transistor, the sixth transistor, the seventh transistor, the eighth transistor and the ninth transistor are connected to the second level signal input terminal, a gate of the fifth transistor, a first terminal of the seventh transistor and a gate of the eighth transistor are connected to the pull-down node, a first terminal of the fifth transistor, a gate of the sixth transistor and a gate of the seventh transistor are connected to the pull-up node, a first terminal of the sixth transistor is connected to the transition node, a first terminal of the seventh transistor is connected to the pull-down node, a first terminal of the eighth transistor and a first terminal of the ninth transistor are connected to the shift signal output terminal, and a gate of the ninth transistor is connected to the second level signal input terminal.

7. The gate driving circuit according to claim 2, wherein the output subcircuit comprises a tenth transistor, a gate of the tenth transistor is connected to the pull-up node, a first terminal of the tenth transistor is connected to the clock signal input terminal, and a second terminal of the tenth transistor is connected to the shift signal output terminal.

8. The gate driving circuit according to claim 2, wherein the energy storage subcircuit comprises a capacitor, a first terminal of the capacitor is connected to the pull-up node, and a second terminal of the capacitor is connected to the output subcircuit.

9. The gate driving circuit according to claim 3, wherein respective transistors are all N-type transistors, the first level signal line inputs a high level, and the second level signal line inputs a low level.

10. A display panel, comprising the gate driving circuit according to claim 1.

11. A method of driving a gate driving circuit having multiple stages of cascaded shift registers, wherein at least two stages of shift registers share a pull-down node potential generation subcircuit, the method comprising:
upon forward scanning, applying a start pulse having a first level on the start signal line, applying a signal having a first level on the first signal line, and applying a signal having a second level on the second signal line,
upon reverse scanning, applying a start pulse having a first level on the start signal line, applying a signal having a second level on the first signal line, and applying a signal having a first level on the second signal line,
wherein at least two stages of shift registers of the gate driving circuit share a pull-down node potential generation subcircuit.

12. The gate driving circuit according to claim 3, wherein respective transistors are all P-type transistors, the first level signal line inputs a low level, and the second level signal line inputs a high level.

13. The gate driving circuit according to claim 4, wherein respective transistors are all N-type transistors, the first level signal line inputs a high level, and the second level signal line inputs a low level.

14. The gate driving circuit according to claim 4, wherein respective transistors are all P-type transistors, the first level signal line inputs a low level, and the second level signal line inputs a high level.

15. The gate driving circuit according to claim 5, wherein respective transistors are all N-type transistors, the first level signal line inputs a high level, and the second level signal line inputs a low level.

16. The gate driving circuit according to claim 5, wherein respective transistors are all P-type transistors, the first level signal line inputs a low level, and the second level signal line inputs a high level.

17. The gate driving circuit according to claim 6, wherein respective transistors are all N-type transistors, the first level signal line inputs a high level, and the second level signal line inputs a low level.

18. The gate driving circuit according to claim 6, wherein respective transistors are all P-type transistors, the first level signal line inputs a low level, and the second level signal line inputs a high level.

19. The gate driving circuit according to claim 7, wherein respective transistors are all N-type transistors, the first level signal line inputs a high level, and the second level signal line inputs a low level.

20. The gate driving circuit according to claim 7, wherein respective transistors are all P-type transistors, the first level signal line inputs a low level, and the second level signal line inputs a high level.
